(19) United States
(12) Patent Application Publication
(10) Pub. No.: US 2018/0342637 A1
(43) Pub. Date: Nov. 29, 2018

(54) SOLAR CELL MODULE

(71) Applicant: Panasonic Corporation, Osaka (JP)

(72) Inventors: Takeshi Nishiwaki, Osaka (JP); Junpei Irikawa, Osaka (JP)

(73) Assignee: Panasonic Corporation, Osaka (JP)

(21) Appl. No.: 15/986,179

(22) Filed: May 22, 2018

(30) Foreign Application Priority Data
May 23, 2017 (JP) 2017-101462

(51) Int. Cl. H01L 31/048; H02S 30/10

(52) U.S. Cl. CPC H01L 31/0481; H02S 30/10

(57) ABSTRACT

A solar cell module which is an example of an embodiment includes a solar cell, a first protective member, a second protective member, a first encapsulant and a second encapsulant. The solar cell is a back contact type cell including a semiconductor substrate and an electrode formed on a rear surface side of the substrate. The first encapsulant has a storage elastic modulus (G1) at 25° C. of 15 MPa or less.

### INCORPORATION BY REFERENCE

The entire disclosure of Japanese Patent Application No. 2017-101462 filed on May 23, 2017, including specification, claims, drawings and abstract is incorporated herein by reference in its entirety.

### TECHNICAL FIELD

The present disclosure generally relates to a solar cell module.

### BACKGROUND

Solar cells generally have a structure in which electrodes are formed on both sides of a semiconductor substrate such as a silicon wafer, and a so-called back contact type cell in which electrodes are formed only on a rear surface side of a semiconductor substrate is also known. For example, International Unexamined Patent Application Publication No. WO 2015/040780 discloses a back contact type cell in which a groove for separating an n-side electrode from a p-side electrode is widely formed in a direction in which the electrodes are separated from each other in an outer circumferential region rather than in an inside region of a main surface of the semiconductor substrate, and a solar cell module using the cell.

### SUMMARY

The back contact type cell has a structure asymmetric between front and back sides in which there is a large difference in shape between a light receiving surface side and a rear surface side, which results in a problem that the cell is susceptible to cracking with a low load. When a load caused by, for example, snowfall acts on the cell of the solar cell module using a back contact type cell, the cell is susceptible to cracking starting from electrodes on the rear surface.

A solar cell module according to an aspect of the present disclosure includes a solar cell, a first protective member provided on a light receiving surface side of the solar cell and a first encapsulant provided between the solar cell and the first protective member, in which the solar cell is a back contact type cell including a semiconductor substrate, and an n-side electrode and a p-side electrode formed on a rear surface side of the substrate, and the first encapsulant has a storage elastic modulus (G1) at 25° C. of 15 MPa or less.

### Advantageous Effects of Invention

According to an aspect of the present disclosure, it is possible to suppress occurrence of cell cracking in a solar cell module using a back contact type solar cell.

### BRIEF DESCRIPTION OF DRAWINGS

The figures depict one or more implementations in accordance with the present teachings, by way of example only, not by way of limitations. In the figures, like reference numerals refer to the same or similar elements.

FIG. 1 is a cross-sectional view of a solar cell panel constituting a solar cell module which is an example of an embodiment;

FIG. 2 is a cross-sectional view of a frame constituting a solar cell module which is an example of the embodiment and the vicinity thereof;

FIG. 3 is a diagram of a solar cell constituting the solar cell module which is an example of the embodiment viewed from a rear surface side;

FIG. 4 is a cross-sectional view along a line AA in FIG. 3; and

FIG. 5 is a diagram illustrating a relationship between a storage elastic modulus (G1) at 25° C. of a first encapsulant and load resistance of the solar cell panel.

### DESCRIPTION OF EMBODIMENTS

Hereinafter, an embodiment of a solar cell module according to the present disclosure will be described in detail with reference to the accompanying drawings. Drawings referred to in the description of the embodiment are schematically described and a dimension ratio or the like among components drawn in the drawings should be judged with the following description taken into consideration.

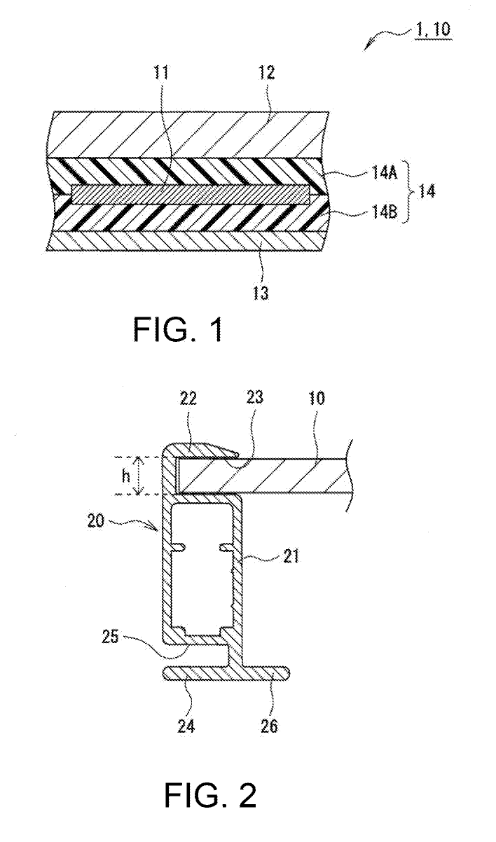

FIG. 1 and FIG. 2 are cross-sectional views of a solar cell module 1 which is an example of the embodiment. As illustrated in FIG. 1 and FIG. 2, the solar cell module 1 is provided with a solar cell 11, a first protective member 12 provided on a light receiving surface side of the solar cell 11, a second protective member 13 provided on a rear surface side of the solar cell 11 and a encapsulant 14 filled between the respective protective members. The encapsulant 14 is composed of a first encapsulant 14A provided between the solar cell 11 and the first protective member 12, and a second encapsulant 14B provided between the solar cell 11 and the second protective member 13. Although details will be described later, the solar cell 11 is a back contact type cell and the first encapsulant 14A has a storage elastic modulus (G1) at 25° C. of 15 MPa or less.

Here, the light receiving surface of the solar cell 11 means a surface on which solar light is mainly made incident (over 50% to 100%) and the “rear surface” means a surface opposite to the light receiving surface. In the present DESCRIPTION, the terms of the light receiving surface and the rear surface are also used for the semiconductor substrate 30 or the like constituting the solar cell 11.

The solar cell module 1 may be composed of only the solar cell panel 10, but the solar cell module 1 in the present embodiment is provided with the solar cell panel 10 and a frame 20 including an inner groove 23 into which a peripheral edge of the solar cell panel 10 is fitted. The solar cell panel 10 is a substantially flat panel composed of the solar cell 11, the first protective member 12, the second protective member 13 and the encapsulant 14. The solar cell panel 10 has a thickness of, for example, less than 6 mm.

The frame 20 includes a frame body 21 having a hollow substantially prism shape and a first hook part 22 erected on a top surface of the frame body 21. The inner groove 23, which is a gap into which the peripheral edge of the solar cell panel 10 can be inserted, is formed between the top surface of the frame body 21 and the first hook part 22. The first hook part 22 extends upward straightforwardly from outside the frame body 21 and is bent inward in the middle and formed to have a substantially L-shaped cross section.

The frame 20 may also include a second hook part 24 erected on an undersurface of the frame body 21 or an outer groove 25 may be formed between the undersurface of the frame body 21 and the second hook part 24. A metal fitting for fixing the solar cell module 1 to a stand frame or the like installed, for example, on a roof is inserted into the outer groove 25. The second hook part 24 extends downward straightforwardly from inside the frame body 21 and is bent outward in the middle and formed to have a substantially L-shaped cross section. An inner flange 26 projecting inside the solar cell module 1 may be formed below the frame 20.

The inner groove 23 of the frame 20 has a height h, that is, a length in a thickness direction of the solar cell panel 10, of preferably 6 mm or less. By setting the height h of the inner groove 23 to 6 mm or less, the gap between the solar cell panel 10 and the frame 20 is reduced and the panel is less likely to warp, making it possible to reduce a load acting on the solar cell 11. Note that the gap between the solar cell panel 10 and the inner groove 23 is filled with silicone resin or the like.

The solar cell module 1 is generally provided with a plurality of solar cells 11. The plurality of solar cells 11 are arranged, for example, on the same plane and the neighboring solar cells 11 are connected in series to each other via a wiring member to form a string of the solar cells 11. Since the solar cell 11 is a back contact type cell, the wiring member is attached to the rear surface side.

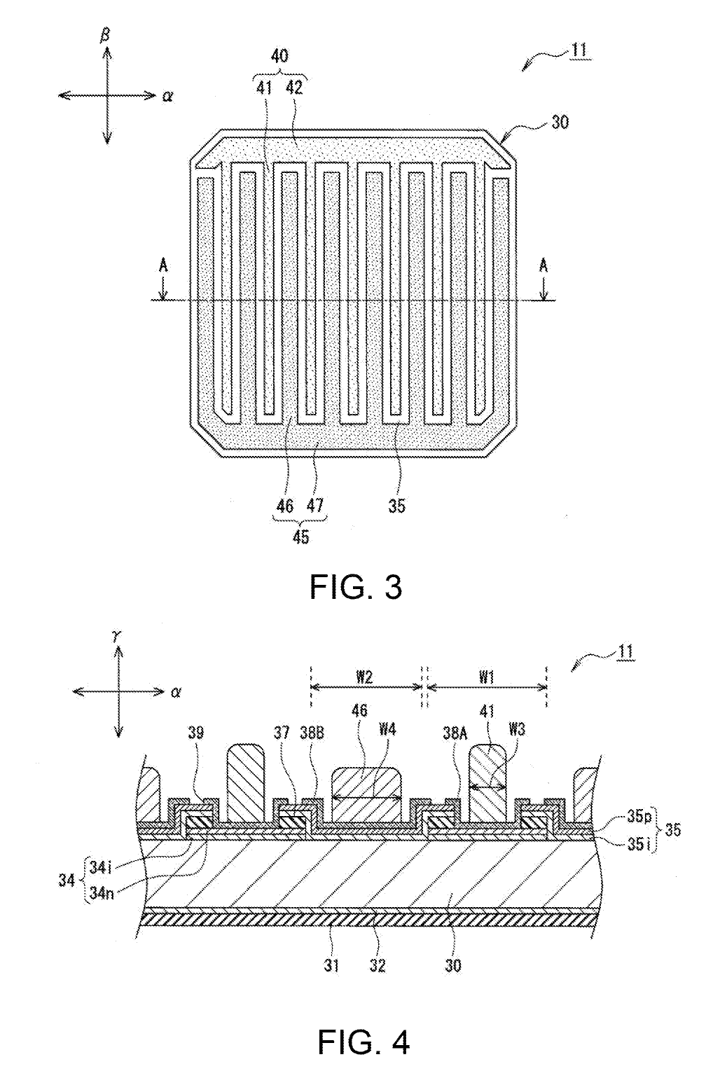

FIG. 3 is a diagram of the solar cell 11 viewed from the rear surface side and FIG. 4 is a cross-sectional view along a line AA in FIG. 3. As shown in FIG. 3 and FIG. 4, the solar cell 11 includes a semiconductor substrate 30, and an n-side electrode 40 and a p-side electrode 45 formed on the rear surface side of the substrate. The n-side electrode 40 is a collector electrode that collects carriers from an n-type semiconductor layer 34 which will be described later. The p-side electrode 45 is a collector electrode that collects carriers from a p-type semiconductor layer 35 which will be described later.

An n-type monocrystalline silicon wafer is preferably used for the semiconductor substrate 30. The semiconductor substrate 30 has a thickness of, for example, 50 to 300 μm. A texture structure (not shown) is preferably formed on a surface of the semiconductor substrate 30. The texture structure is a surface concavo-convex structure for suppressing surface reflection and increasing an amount of light absorption of the semiconductor substrate 30, is preferably formed at least on the light-receiving surface, or may also be formed on both the light receiving surface and the rear surface. The semiconductor substrate may have n-type conductivity or p-type conductivity.

The solar cell 11 includes a protective layer 31 formed on the light receiving surface side of the semiconductor substrate 30. The protective layer 31 is an insulating layer composed of, for example, silicon nitride, silicon oxide, silicon oxynitride, and also functions as a reflection prevention layer for suppressing reflection of incident light. A passivation layer 32 for suppressing carrier recoupling on the light-receiving side of the substrate is interposed between the semiconductor substrate 30 and the protective layer 31. The passivation layer 32 is formed into a laminated structure formed by laminating, for example, substantially intrinsic amorphous silicon (hereinafter referred to as “i-type amorphous silicon”) or i-type amorphous silicon and n-type amorphous silicon in this order from the light receiving surface of the semiconductor substrate 30.

The solar cell 11 includes the n-type semiconductor layer 34 and the p-type semiconductor layer 35 respectively formed on the rear surface side of the semiconductor substrate 30. The n-type semiconductor layer 34 and the p-type semiconductor layer 35 are provided on the rear surface of the semiconductor substrate 30 in a comb-tooth form. The respective comb-tooth parts of the n-type semiconductor layer 34 and the p-type semiconductor layer 35 are provided so as to be interposed with each other into a structure in which the respective comb-tooth parts are alternately arrayed in an α-direction.

In the present embodiment, an n-type amorphous semiconductor layer is used as the n-type semiconductor layer 34. The n-type amorphous semiconductor layer has a laminated structure formed by laminating an i-type amorphous silicon layer 34i and an n-type amorphous silicon layer 34n in this order from the rear surface of the semiconductor substrate 30. The i-type amorphous silicon layer 34i is provided on the rear surface of the semiconductor substrate 30 in contact with the rear surface. The n-type amorphous silicon layer 34n is provided on the i-type amorphous silicon layer 34i in contact with the i-type amorphous silicon layer 34i. On the other hand, a p-type amorphous semiconductor layer is used as the p-type semiconductor layer 35. The p-type amorphous semiconductor layer has a laminated structure formed by laminating an i-type amorphous silicon layer 35i and a p-type amorphous silicon layer 35p in this order from the rear surface of the semiconductor substrate. The i-type amorphous silicon layer 35i is provided on the rear surface of the semiconductor substrate 30 in contact with the rear surface. The p-type amorphous silicon layer 35p is provided on the i-type amorphous silicon layer 35i in contact with the i-type amorphous silicon layer 35i.

The n-type semiconductor layer 34 and the p-type semiconductor layer 35 are not limited to those described above. One of the n-type semiconductor layer 34 and the p-type semiconductor layer 35 is intended to reduce a density of minority carriers in the vicinity of a junction interface with the semiconductor substrate 30 to thereby suppress recoupling of photocarriers in the vicinity of the junction interface with the semiconductor substrate 30. The other of the n-type semiconductor layer 34 and the p-type semiconductor layer 35, which is different from the above-described one, is intended to form a pn junction in the vicinity of the junction interface with the semiconductor substrate 30. For example, an n-type crystalline silicon layer may be used as the n-type semiconductor layer 34 and a p-type crystalline silicon layer may be used as the p-type semiconductor layer 35.

In the present embodiment, the solar cell 11 includes an insulating layer 37 on the rear surface side of the semiconductor substrate 30. The semiconductor substrate 30 includes a region on the rear surface side where the p-type semiconductor layer 35 is superimposed on the n-type semiconductor layer 34 in a γ-direction. In this superimposed region, the insulating layer 37 is interposed between the n-type semiconductor layer 34 and the p-type semiconductor layer 35. The insulating layer 37 is an insulating layer composed of, for example, silicon nitride, silicon oxide, or silicon oxynitride.

The semiconductor substrate 30 includes a first region on the rear surface thereof corresponding to a junction surface between the semiconductor substrate 30 and the n-type semiconductor layer 34. Furthermore, the semiconductor substrate 30 includes a second region on the rear surface thereof corresponding to the junction surface between the semiconductor substrate 30 and the p-type semiconductor layer 35. The second region is a region on the rear surface of the semiconductor substrate 30 which is different from the first region. The first region and the second region are provided over substantially the whole rear surface of the semiconductor substrate. The first region and the second region are provided on the rear surface of the semiconductor substrate 30 in a comb-tooth form. The respective comb-tooth parts of the first region and the second region are provided so as to be interposed with each other into a structure in which the respective comb-tooth parts are alternately arrayed in an α-direction. As shown in FIG. 4, the width of the comb-tooth part of the first region in the α-direction is assumed to be W1 and the width of the comb-tooth part of the second region in the α-direction is assumed to be W2.

As illustrated in FIG. 3 and FIG. 4, the n-side electrode 40 is formed on the n-type semiconductor layer 34 and includes a plurality of fingers 41 extending substantially parallel to each other and a bus bar 42 substantially orthogonal to each finger 41. The p-side electrode 45 is formed on the p-type semiconductor layer 35. As in the case of the n-side electrode 40, the p-side electrode 45 includes a plurality of fingers 46 and a bus bar 47. On the rear surface of the semiconductor substrate 30, the fingers 41 and 46 extend in a β-direction and the bus bars 42 and 47 extend in the α-direction.

The fingers 41 and 46 are alternately formed in the α-direction in correspondence with the first region and the second region which are formed into a stripe shape. The finger 46 is formed to be wider than the finger 41. The n-side electrode 40 and the p-side electrode 45 each have a comb-tooth shape, engaging with each other without contacting each other and are respectively formed into a stripe shape. The bus bars 42 and 47 are provided with wiring members to connect the solar cells 11 in series to each other and modularize them.

In the present embodiment, the solar cell 11 further includes a transparent conductive layer 38A formed between the n-type semiconductor layer 34 and the n-side electrode 40 and a transparent conductive layer 38B formed between the p-type semiconductor layer 35 and the p-side electrode 45. The transparent conductive layers 38A and 38B are separated from each other by a groove 39 formed at a position superimposed on the insulating layer 37 in the thickness direction (γ-direction) of the substrate. The transparent conductive layers 38A and 38B are composed of a transparent conductive oxide (IWO, ITO or the like) which is a metal oxide such as indium oxide (In₂O₃), zinc oxide (ZnO) doped with tungsten (W), tin (Sn), antimony (Sb) or the like.

The n-side electrode 40 and the p-side electrode 45 may be formed using a conductive paste, but are preferably formed through electrolytic plating. The n-side electrode 40 and the p-side electrode 45 are made of a metal such as nickel (Ni), copper (Cu) or silver (Ag) or may also have a laminated structure with a Ni layer and a Cu layer or may also include a tin (Sn) layer on an outermost surface to improve corrosion resistance. The n-side electrode 40 and the p-side electrode 45 have a thickness of, for example, 10 μm to 60 μm.

The finger 41 of the n-side electrode 40 is formed in the first region on the rear surface of the semiconductor substrate 30. The finger 41 of the n-side electrode 40 has a width W3 preferably less than 80% of the width W1 of the first region and more preferably less than 60%. Similarly, the finger 46 of the p-side electrode 45 is formed in the second region on the rear surface of the semiconductor substrate 30. The finger 46 of the p-side electrode 45 has a width W4 preferably less than 80% of the width W2 of the second region and more preferably less than 60%. The widths W3 and W4 of the fingers 41 and 46 of the n-side electrode 40 and the p-side electrode 45 are the widths in the α-direction at an intermediate position of the thickness direction of each finger. In this case, the edges of the fingers 41 and 46 are formed at positions not overlapping the insulating layer 37, making the solar cell 11 along the edges less susceptible to cracking. Note that the bus bars 42 and 47 are also preferably formed so as to have widths less than 80% of the widths of the first and second regions, and more preferably less than 60%.

As described above, the solar cell 11 is sandwiched between the first protective member 12 and the second protective member 13 and sealed with the encapsulant 14 which is filled between the respective protective members.

A transparent member such as a glass substrate or a resin substrate may be used for the first protective member 12. Among these members, the glass substrate may be preferably used from the standpoint of fire resistance, load resistance or the like. The thickness of the glass substrate is preferably 3.2 mm or more or more, preferably 4.0 mm or more, in order to reduce a load acting on the solar cell 11 and suppress cracking of the cell. An example of preferable range of thickness is 3.2 mm to 5.5 mm.

The same transparent member as that of the first protective member 12, or an opaque member, may be used for the second protective member 13. For example, a resin sheet thinner than the glass substrate used for the first protective member 12 may be used for the second protective member 13. The material of the resin sheet is not particularly limited but may be preferably polyethylene terephthalate (PET). The thickness of the resin sheet is not particularly limited but may preferably be 50 μm to 300 μm.

As described above, the encapsulant 14 is composed of a first encapsulant 14A interposed between the solar cell 11 and the first protective member 12 and a second encapsulant 14B interposed between the solar cell 11 and the second protective member 13. The first encapsulant 14A has a storage elastic modulus (G1) at 25° C. of 15 MPa or less. The first encapsulant 14A and the second encapsulant 14B are made of resin having different storage elastic moduli, and the storage elastic modulus (G1) of the first encapsulant 14A is preferably lower than a storage elastic modulus (G2) at 25° C. of the second encapsulant 14B. By satisfying G1≤15 MPa and preferably G1<G2, it is possible to reduce a load acting on the solar cell 11 and suppress cracking of the solar cell 11 when the solar cell panel 10 is warped due to snowfall or the like.

The storage elastic modulus refers to a ratio of elastic stress having the same phase with distortion to the distortion and is expressed by a real number part of a complex modulus of elasticity. The smaller the numerical value of the storage elastic modulus, the lower the elasticity of resin becomes. The storage elastic moduli of the first encapsulant 14A and second encapsulant 14B may be measured using a dynamic viscoelasticity measuring apparatus under a temperature condition of 25° C.

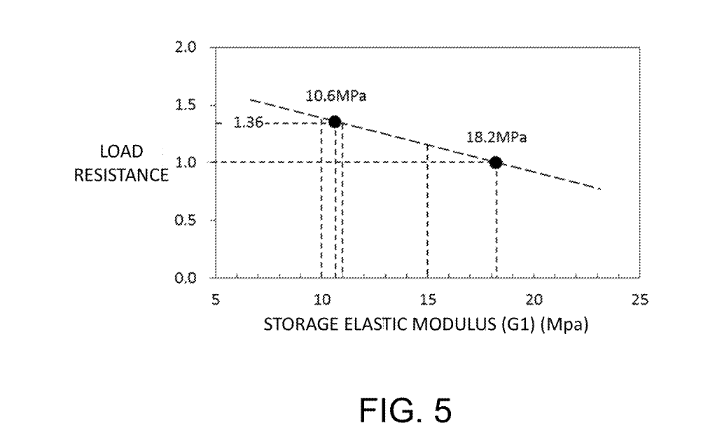

FIG. 5 illustrates load resistance of the solar cell panel 10 when the storage elastic modulus (G1) at 25° C. of the first encapsulant 14A varies. The load resistance which is the vertical axis of FIG. 5 refers to a load ratio (Z1/Z0), where Z0 is a load obtained when a load is gradually applied to the solar cell panel 10 in which the storage elastic modulus (G1) at 25° C. of the first encapsulant 14A is 18.2 MPa and cracking occurs in the solar cell 11 of the solar cell panel 10, and Z0 is assumed to be 1, and Z1 is a load obtained when a load is gradually applied to the solar cell panel 10 in which the storage elastic modulus (G1) at 25° C. is 10.6 MPa and the solar cell 11 of the solar cell panel 10 is cracked. As shown in FIG. 5, the load resistance improves as the storage elastic modulus (G1) of the first encapsulant 14A is lowered. The load resistance is higher when the storage elastic modulus (G1) of the first encapsulant 14A is 10.6 MPa than when the storage elastic modulus (G1) is 18.2 MPa. For example, the storage elastic modulus (G1) at 25° C. of the first encapsulant 14A is 15 MPa or less, preferably 11 MPa or less and more preferably 10 MPa or less.

The ratio (G1/G2) of the storage elastic modulus (G1) of the first encapsulant 14A to the storage elastic modulus (G2) of the second encapsulant 14B is preferably 0.7 or less. As described above, the storage elastic modulus (G1) of the first encapsulant 14A is set to be 15 MPa or less and the storage elastic modulus (G2) of the second encapsulant 14B is set to satisfy, for example, G1/G2≤0.7. In this case, it is much easier to suppress cracking of the solar cell 11.

Examples of resin that constitutes the first encapsulant 14A may include epoxy resin and polyolefin. In particular, polyolefin containing a crosslinking agent is suitable. Resin that constitutes the second encapsulant 14B is not particularly limited as long as it satisfies a condition of G1<G2. Examples of resin that constitutes the second encapsulant 14B may include epoxy resin, polyolefin and ethylene-vinyl acetate copolymer (EVA).

The first encapsulant 14A and the second encapsulant 14B are each made up of a resin sheet having a thickness of, for example, 100 μm to 1000 μm. The solar cell module 1 may be manufactured by laminating a string of the solar cells 11 connected via wiring members using the first protective member 12, the second protective member 13, a resin sheet constituting the first encapsulant 14A, and a resin sheet constituting the second encapsulant 14B.

According to the solar cell module 1 provided with the above-described configuration, it is possible to reduce a load acting on the solar cell 11 when the solar cell panel 10 is warped due to snowfall or the like and suppress cracking of the solar cell 11. Furthermore, by forming the n-side electrode 40 and the p-side electrode 45 so as to have widths less than 80% of the widths of the n-type and p-type regions, even when a load acts on the solar cell 11, it is possible to make it unlikely for cracking of the cell to occur starting from the electrodes.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

1. A solar cell module comprising:
a solar cell;
a first protective member provided on a light receiving surface side of the solar cell; and
a first encapsulant provided between the solar cell and the first protective member, wherein
the solar cell is a back contact type cell comprising a semiconductor substrate, and an n-side electrode and a p-side electrode formed on a rear surface side of the substrate, and
the first encapsulant has a storage elastic modulus (G1) at 25° C. of 15 MPa or less.

2. The solar cell module according to claim 1, further comprising:
a second protective member provided on the rear surface side of the solar cell; and
a second encapsulant provided between the solar cell and the second protective member, wherein
the storage elastic modulus (G1) at 25° C. of the first encapsulant is lower than a storage elastic modulus (G2) at 25° C. of the second encapsulant.

3. The solar cell module according to claim 2, wherein a ratio (G1/G2) of the storage elastic modulus (G1) at 25° C. of the first encapsulant to the storage elastic modulus (G2) at 25° C. of the second encapsulant is 0.7 or less.

4. The solar cell module according to claim 1, wherein the solar cell comprises an n-type semiconductor layer and a p-type semiconductor layer on the rear surface of the semiconductor substrate.

5. The solar cell module according to claim 4, wherein
the n-type semiconductor layer is an n-type amorphous semiconductor layer, and
the p-type semiconductor layer is a p-type amorphous semiconductor layer.

6. The solar cell module according to claim 4, wherein
the semiconductor substrate comprises, on the rear surface:
a first region corresponding to a junction surface between the n-type semiconductor layer the and the semiconductor substrate; and
a second region corresponding to a junction surface between the p-type semiconductor layer the and the semiconductor substrate,
the n-side electrode is formed in the first type region,
the p-side electrode is formed in the second type region,
the width of the n-side electrode is less than 80% of the width of the first region, and
the width of the p-side electrode is less than 80% of the width of the second region.

7. The solar cell module according to claim 1, wherein the first encapsulant includes polyolefin containing a crosslinking agent.

8. The solar cell module according to claim 1, comprising:
a solar cell panel comprising:
the solar cell;
the first protective member;
the second protective member;
the first encapsulant; and
the second encapsulant, and
a frame comprising an inner groove into which a peripheral edge of the solar cell panel is fitted,
wherein the inner groove has a height of 6 mm or less.

9. The solar cell module according to claim 1, wherein the first protective member is a glass substrate having a thickness of 3.2 mm or greater.
